(19) United States
(12) Patent Application Publication
(10) Pub. No.: US 2025/0105084 A1
(43) Pub. Date: Mar. 27, 2025

(54) SEMICONDUCTOR PACKAGE AND METHOD OF FORMING THE SAME

(71) Applicant: Taiwan Semiconductor Manufacturing Co., Ltd., Hsinchu (TW)

(72) Inventors: Yu-Chia Lai, Zhunan Township (TW); Chen-Shien Chen, Zhubei City (TW); Ting Hao Kuo, Hsinchu (TW); Jen-Yuan Chang, Hsinchu (TW)

(21) Appl. No.: 18/530,102

(22) Filed: Dec. 5, 2023

Related U.S. Application Data
(60) Provisional application No. 63/584,549, filed on Sep. 22, 2023.

(51) Int. Cl. H01L 23/367; H01L 23/00; H01L 23/48; H01L 23/498; H01L 25/00; H01L 25/065

(52) U.S. Cl. CPC H01L 23/367; H01L 23/481; H01L 24/08; H01L 24/32; H01L 25/0652; H01L 25/50; H01L 23/49816; H01L 2224/08145; H01L 2224/32145; H01L 2224/32225; H01L 2924/181

(57) ABSTRACT

A method includes forming a dummy component, including: forming through-substrate vias (TSVs) in a substrate; forming a thermal structure over the TSVs, wherein the thermal structure includes metal lines in dielectric layers; forming a bonding layer over the thermal structure; and forming bond pads within the bonding layer; bonding the dummy component to a package component; and bonding a semiconductor die to the package component.

### PRIORITY CLAIM AND CROSS-REFERENCE

This application claims the benefit of U.S. Provisional Application No. 63/584,549, filed on Sep. 22, 2023, which application is hereby incorporated herein by reference.

### BACKGROUND

With the increasing higher degree of integration level of integrated circuits, more and more devices are compacted into smaller areas. In the meantime, to improve the speed of the integrated circuits, the driving currents of the integrated circuits also become higher. The heat dissipation of the integrated circuits thus becomes more demanding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a package component, in accordance with some embodiments.

FIGS. 2, 3, 4, 5, and 6 illustrate cross-sectional views of intermediate steps in the formation of a package, in accordance with some embodiments.

FIGS. 7, 8, 9, and 10 illustrate cross-sectional views of intermediate steps in the formation of a thermal component, in accordance with some embodiments.

FIGS. 11A, 11B, 11C, 11D, and 11E illustrate various thermal components, in accordance with some embodiments.

FIGS. 12A, 12B, 12C, 12D, 12E, 12F, 12G, and 12H illustrate various cross-sectional shapes of through-substrate vias, in accordance with some embodiments.

FIGS. 13, 14, 15, 16, 17, and 18 illustrate cross-sectional views of intermediate steps in the formation of a package, in accordance with some embodiments.

FIGS. 19, 20, 21, and 22 illustrate cross-sectional views of intermediate steps in the formation of a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A heat-dissipating package component and the method of forming the same are provided. In accordance with some embodiments of the present disclosure, thermally conductive through-substrate vias (TSVs) are formed to extend into a semiconductor substrate of a dummy component within a package. The TSVs provide improved heat dissipation. A dummy component may also include thermally conductive features such as metal lines, metal vias, or the like, which can provide additional improvement to heat dissipation. The thermally conductive TSVs and/or thermally conductive features may be configured to provide efficient heat dissipation according to the design of the package.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

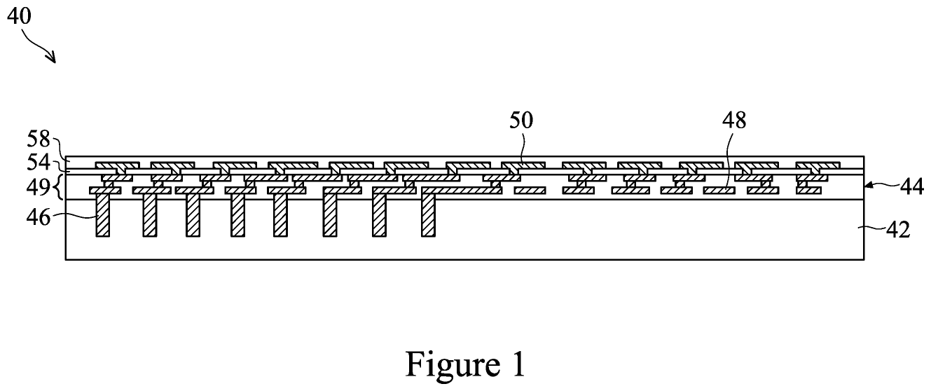

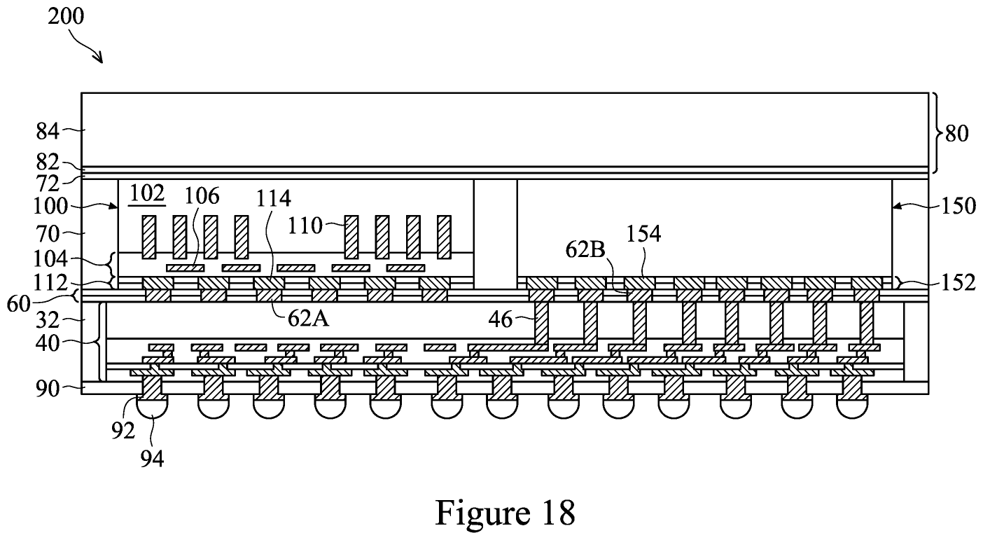

FIGS. 1 through 6 illustrate cross-sectional views of intermediate steps in the formation of a package 200 (see FIG. 18), in accordance with some embodiments. In FIG. 1, a first package component 40 is formed or provided, for example, in a wafer (not separately illustrated). In accordance with some embodiments, first package components 40 are individual device dies (e.g., integrated circuit dies), packages having one or more device dies packaged therein, System-on-Chip (SoC) dies including a plurality of integrated circuits integrated as a system, or the like. The device die(s) of first package components 40 may be or may comprise logic dies, memory dies, input-output (I/O) dies, Integrated Passive Devices (IPDs), the like, or combinations thereof. For example, the logic device die(s) of first package components 40 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) of first package components 40 may include Static Random Access Memory (SRAM) dies, Dynamic Random Access Memory (DRAM) dies, or the like. The device die(s) of first package components 40 may include semiconductor substrates and interconnect structures.

In accordance with some embodiments, the first package component 40 may include a substrate 42. The substrate 42 may be a semiconductor substrate, such as a bulk semiconductor, a semiconductor-on-insulator (SOI) substrate, or the like, which may be doped (e.g., with a p-type or an n-type dopant) or undoped. The substrate 42 may be a wafer, such as a silicon wafer. Other substrates, such as a silicon-on-insulator (SOI) substrate, a multi-layered substrate, or a gradient substrate may also be used. In some embodiments, the semiconductor material of the substrate 42 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, multiple first package components 40 may be formed on the same substrate 42 and then separated into individual first package components 40 using a singulation process (e.g., a sawing process, dicing process, or the like).

Further, integrated circuit devices (not separately illustrated) may be formed at a front-side surface of the substrate 42, in some embodiments. The integrated circuit devices may include active devices (e.g., NMOS and PMOS transistors, diodes, etc.), passive devices (e.g., resistors, capacitors, etc.), and the like. In addition, through-substrate vias (TSVs) 46 may be formed extending partially through the substrate 42.

In some embodiments, an interconnect structure 49 is formed over the front-side of the substrate 42. The interconnect structure 49 includes conductive features 48 (e.g., metal lines, metal vias, metal pads, etc.) formed in one or more dielectric layers 44. Conductive features 48 of the interconnect structure 49 may be electrically connected to the integrated circuit devices and/or the TSVs 46. As illustrated, the interconnect structure 49 may include multiple layers of conductive features 48 formed in multiple dielectric layers 44. The conductive features 48 may be formed using a damascene process, a dual damascene process, or another suitable technique. The conductive features 48 may comprise, for example, copper, aluminum, tungsten ruthenium, cobalt, alloys thereof, combinations thereof, or the like. The dielectric layers 44 may be formed of or comprise a dielectric material such as polymer, silicon nitride, silicon oxide, silicon oxynitride, silicon oxycarbide, silicon carbonitride, the like, combinations thereof, and/or multi-layers thereof. Other materials are possible. In some cases, the dielectric layers 44 may be Inter-Metal Dielectric (IMD) layers. The interconnect structure 49 shown in FIG. 1 is an example, and an interconnect structure 49 may comprise another number of layers or may have a different configuration than shown. In some embodiments, the interconnect structure 49 may comprise a seal ring (not shown).

A passivation layer 54 may be formed over the interconnect structure 49, in accordance with some embodiments. The passivation layer 54 may be formed of a non-low-k dielectric material having a dielectric constant equal to or greater than the dielectric constant of silicon oxide, in some embodiments. The passivation layer 54 may be formed of or comprise an inorganic dielectric material, which may include a material selected from, but not limited to, silicon nitride, silicon oxide, silicon oxynitride, silicon oxycarbide, silicon carbonitride, the like, combinations thereof, and/or multi-layers thereof. Other materials are possible.

Metal pads 50 may be formed on the passivation layer 54, in accordance with some embodiments. The metal pads 50 are formed on the passivation layer 54 and may have portions extending through the passivation layer 54 to physically and electrically contact conductive features 48 of the interconnect structure 49. The metal pads 50 can help facilitate external electrical connection to the integrated circuit of first package components 40 during functional use and/or facilitate external electrical connection during, for example, wafer acceptance testing (e.g., circuit probe testing) of the first package components 40. Some of the metal pads 50 may be connected to TSVs 46 by interconnect structure 49. Some of the metal pads 50 may be connected to the integrated circuit devices at the surface of the substrate 42 by interconnect structure 49.

As an example of forming the metal pads 50, the passivation layer 54 may be patterned using photolithographic and etching techniques to expose the interconnect structure 49. The patterned passivation layer 54 exposes top-most conductive features 48 of the interconnect structure 49. A seed layer (not shown) may be deposited over the passivation layer 54 and on the exposed conductive features 48. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, sputtering, evaporation, Physical Vapor Deposition (PVD), Chemical Vapor Deposition (CVD), Plasma Enhanced Chemical Vapor Deposition (PECVD), or the like. A photoresist (not shown) is then formed and patterned on the seed layer. The photoresist may be formed by spin coating or the like and may be exposed to light for patterning. The pattern of the photoresist corresponds to the metal pads 50. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal such as aluminum copper, copper, aluminum, nickel, tungsten, the like, or alloys thereof. Other conductive materials are possible. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed using an acceptable etching process, such as a wet etching process or dry etching process. The remaining portions of the seed layer and conductive material form the metal pads 50.

In some embodiments, a dielectric layer 58 may be deposited over the passivation layer 54 and the metal pads 50. The dielectric layer 58 may protect the metal pads 50, for example, from oxidization. In some embodiments, the dielectric layer 58 is an anti-reflective coating (ARC) and comprises an oxide or a nitride, such as silicon oxide (SiO), silicon nitride (SiN), silicon oxynitride (SiON), or any suitable material. In other embodiments, the dielectric layer 58 may include one or more materials such as Phospho-Silicate Glass (PSG), Boro-Silicate Glass (BSG), Boron-Doped Phospho-Silicate Glass (BPSG), undoped Silicate Glass (USG), low-k dielectric materials, or the like. The dielectric layer 58 may be formed using a suitable process such as spin coating, Flowable Chemical Vapor Deposition (FCVD), PECVD, Low Pressure Chemical Vapor Deposition (LPCVD), or the like. Other materials or deposition techniques are possible. In some embodiments, an optional planarization process (e.g., Chemical Mechanical Polish (CMP), grinding, or the like) is performed on the dielectric layer 58 such that the top surface of the dielectric layer 58 is approximately planar.

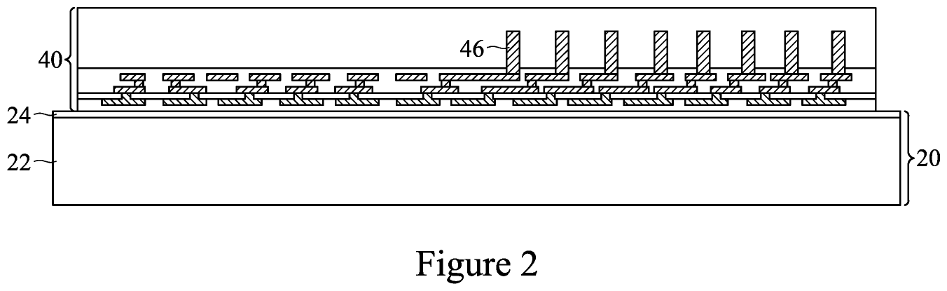

In FIG. 2, one or more first package components 40 are attached to a first carrier 20, in accordance with some embodiments. The first carrier 20 may include a base carrier 22 and one or more dielectric bond layers 24. In some embodiments, the base carrier 22 may be a wafer and may be a similar material as the substrate 42 of the first package component 40. In this manner, during process, warpage caused by a mismatch of Coefficients of Thermal Expansion (CTE) between the first carrier 20 and the first package component 40 may be reduced. For example, in some embodiments, the base carrier 22 may be formed of or comprise silicon. Other embodiments may use other materials such as laminate, ceramic, glass, silicate glass, organic core, the like, or a combination thereof. In accordance with some embodiments, the entire base carrier 22 is formed of a homogeneous material, with no other material different from the homogeneous material therein. In some embodiments, the entire base carrier 22 may be formed of silicon (doped or undoped), and without a metal region, dielectric region, etc., therein.

Before attaching the first package component 40 to the first carrier 20, a dielectric bond layer 24 may be deposited on the base carrier 22. The dielectric bond layer 24 may include one layer or multiple layers comprising one or more materials such as oxide-based materials such as silicon oxide (SiO), PSG, BSG, BPSG, fluorine-doped silicate glass (FSG), or the like; nitride-based materials such as silicon nitride (SiN) or the like; oxynitride based materials such as silicon oxynitride (SiON) or the like; or other materials such as silicon oxycarbide (SiOC), silicon carbonitride (SiCN), or the like. Dielectric bond layers 24 may be formed using spin coating, FCVD, PECVD, LPCVD, Atomic Layer Deposition (ALD), the like, or a combination thereof. For example, in some embodiments, the dielectric bond layers 24 may include a lowermost layer (e.g., proximal to base carrier 22) comprising an oxide, one or more middle layers comprising a nitride and/or an oxynitride, and an uppermost layer (e.g., distal from base carrier 22) comprising an oxynitride (e.g., with a lower nitrogen-to-oxygen ratio as compared with the middle layers). Although not separately illustrated, alignment marks may be formed in the dielectric bonding layers 24 (e.g., the uppermost layer) using any suitable method.

In some embodiments, the first package component 40 is attached to the first carrier 20 using a direct bonding process, such as fusion bonding or dielectric-to-dielectric bonding. In accordance with some embodiments, the bonding of the first package component 40 to the first carrier 20 includes pre-treating the dielectric bond layers 24 and/or the dielectric layers 58 with a process gas comprising oxygen (O₂) and/or nitrogen (N₂), performing a pre-bonding process to bond dielectric bond layers 24 and dielectric layers 58 together, and performing an annealing process following the pre-bonding process to strengthen the bond.

In accordance with some embodiments, during the pre-bonding process, the first package component 40 is put into physical contact with the first carrier 20, with a pressing force applied to press the first package component 40 against the first carrier 20. The pre-bonding process may be performed at room temperature (e.g., in the range of about 20° C. to about 25° C.), though a higher temperature may also be used. After the pre-bonding process, an annealing process is performed to bond the dielectric bond layers 24 and dielectric layers 58 together. In accordance with some embodiments, the annealing process is performed at a temperature in the range of about 200° C. to about 350° C. The annealing duration may be in a range from 30 minutes to 60 minutes. Other pre-bonding process or bonding processes are possible.

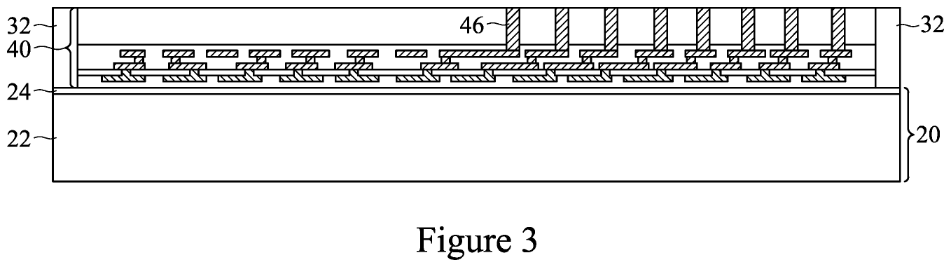

In FIG. 3, a gap-filling material 32 is deposited over the first package component 40 and the first carrier 20, in accordance with some embodiments. The gap-filling material 32 may encapsulate, protect, and/or insulate the first package component 40. In some embodiments, the gap-filling material 32 may include an optional liner layer and a bulk layer (not separately illustrated). For example, the liner layer may be a conformal layer extending along the top surfaces and the sidewalls of the first package component 40 and along top surfaces of the dielectric bond layer 24. The liner layer may also be referred to as a seal-ring and, in some embodiments, is used as an etch stop layer in subsequent steps. The liner layer may be formed of a dielectric material such as silicon nitride, silicon oxide, the like, or a combination thereof. The liner layer may be deposited using a suitable conformal deposition process such as ALD, CVD, or the like. The bulk layer of the gap-filling material 32 may be formed of a molding compound, an epoxy, a resin, a nitride such as silicon nitride, an oxide such as silicon oxide, an insulating material, the like, or a combination thereof. The bulk layer may be deposited using a suitable process, such as compression molding, spin coating, FCVD, PECVD, LPCVD, ALD, or the like.

In some embodiments, a planarization process is then performed to remove portions of the gap-filling material 32. The planarization process may include, for example, a CMP process, a grinding process, and etching process, or the like. The planarization process may remove gap-filling material 32 such that the first package components 40 are exposed, as shown in FIG. 3. Further, the planarization process may remove portions of the substrate 42 of the first package component 40 such that the TSVs 46 of the first package component 40 are exposed, as shown in FIG. 3. In some embodiments, the substrate 42 may be recessed using an etching process such that the TSVs 46 protrude from the surface of the substrate 42. After performing the planarization process, surfaces of the gap-filling material 32, substrate 42, and/or TSVs 46 may be level or coplanar (within process variations).

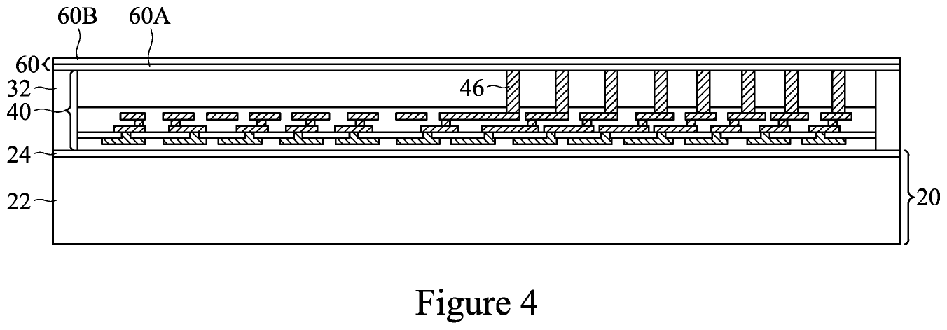

In FIG. 4, a dielectric bond layer 60 is formed on the gap-filling material 32 and the first package component 40, in accordance with some embodiments. The dielectric bond layer 60 may be deposited on surfaces of the gap-filling material 32, the substrate 42, and the TSVs 46. The dielectric bond layer 60 may include one layer or multiple layers. For example, the dielectric bond layer 60 is shown as being formed of a first dielectric layer 60A deposited on the gap-filling material 32 and the first package component 40 and a second dielectric layer 60B deposited on the first dielectric layer 60A. In other embodiments, the dielectric bond layer 60 may be formed of a single layer or of more than two layers. In some embodiments, the dielectric bond layer 60 may comprise one or more materials, which may include oxide-based materials such as silicon oxide (SiO), PSG, BSG, BPSG, FSG, USG, or the like; nitride-based materials such as silicon nitride (SiN) or the like; oxynitride based materials such as silicon oxynitride (SiON) or the like; or other materials such as silicon oxycarbide (SiOC), silicon carbonitride (SiCN), or the like. The dielectric bond layer 60 may be formed using spin coating, FCVD, PECVD, LPCVD, ALD, the like, or a combination thereof. For example, in some embodiments, the dielectric bond layer 60 may include a first dielectric layer 60A comprising silicon oxide and a second dielectric layer 60B comprising silicon oxynitride, though other combinations of materials are possible.

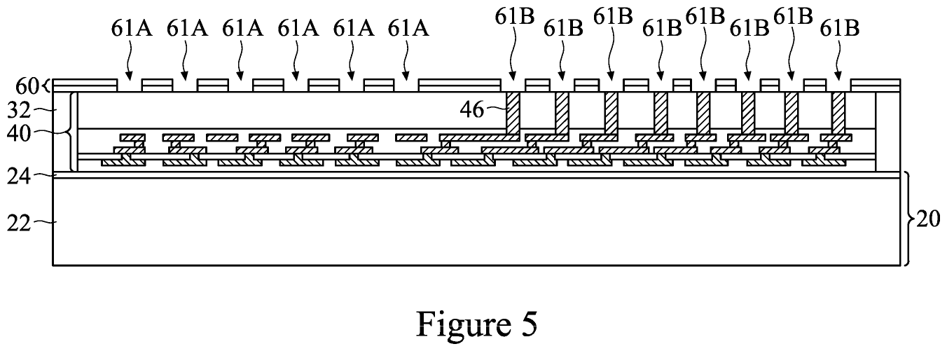

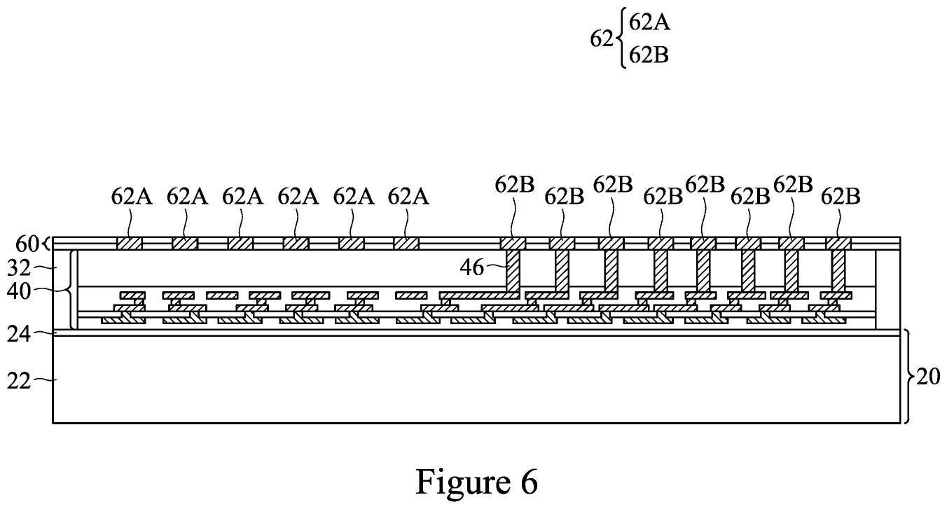

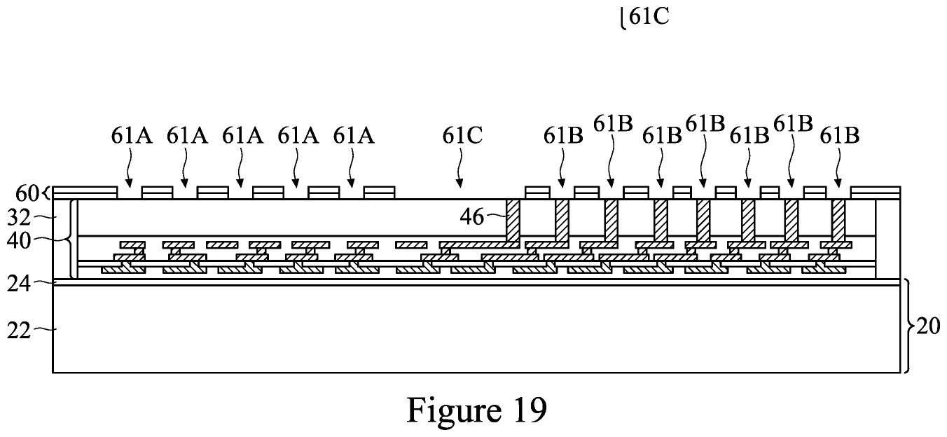

In FIG. 5, openings 61 (e.g., openings 61A and 61B) are patterned in the dielectric bond layer 60, in accordance with some embodiments. Bond pads 62 (see FIG. 6) are subsequently formed in the openings 61. The openings 61 may expose the TSVs 46. For example, in FIG. 5, the openings 61 includes openings 61B that expose TSVs 46 and openings 61A that do not expose TSVs 46. The openings 61 may be patterned using suitable photolithography and etching techniques. For example, a patterned mask may be formed over the dielectric bond layer 60, and the dielectric bond layer 60 may be etched using the patterned mask. The etching may include one or more etching steps, each of which may include a wet etching process and/or a dry etching process. In some embodiments, thermal routing 62C (see FIGS. 19-22) may also be subsequently formed in the openings 61.

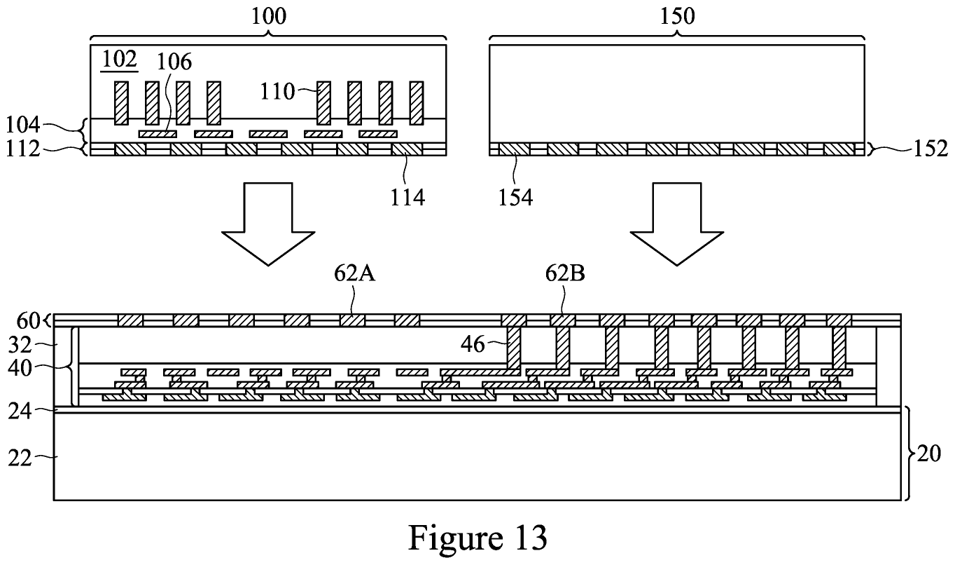

In FIG. 6, bond pads 62 (e.g., bond pads 62A and 62B) are formed in the openings 61, in accordance with some embodiments. The bond pads 62 are used to form physical, electrical, and/or thermal connections to subsequently bonded components, such as thermal components 100 or active package components 150 (see FIG. 13). The bond pads 62 may be electrically isolated or may be electrically connected to the TSVs 46. For example, in FIG. 6, bond pads 62A are electrically isolated, and bond pads 62B physically and electrically contact TSVs 46.

The bond pads 62 may be formed using a damascene process, a dual damascene process, or another suitable technique. The bond pads 62 may comprise material(s) similar to those described previously for the metal pads 50 and may be formed using similar techniques. For example, in some embodiments, a seed layer may be deposited in the openings 61 and then a conductive material may be deposited on the seed layer using a plating process. A planarization process (e.g., CMP or grinding) may be performed, in some embodiments. The planarization process may remove excess conductive material, and after performing the planarization process, surfaces of the bond pads 62 and the dielectric bond layer 60 may be approximately level or coplanar.

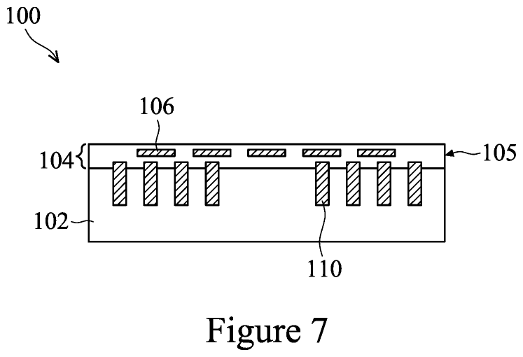

FIGS. 7 through 10 illustrate cross-sectional views of intermediate steps in the formation of a thermal component 100, in accordance with some embodiments. The thermal component 100 is a package component that provides structural support for a package (e.g., package 200 of FIG. 18) and/or facilitates heat dissipation within a package. In some embodiments, the thermal component 100 is free of active and/or passive devices. In this manner, the thermal component 100 may be considered a dummy die, in some cases.

In accordance with some embodiments, the thermal component 100 may include a substrate 102. The substrate 102 may be a semiconductor substrate, which may be similar to those described previously for the substrate 42. For example, in some embodiments, the substrate 102 may be a silicon substrate, though other materials are possible. In some embodiments, multiple thermal components 100 may be formed on the same substrate 102 and then separated into individual thermal components 100 using a singulation process (e.g., a sawing process, dicing process, or the like).

Through-substrate vias (TSVs) 110 may be formed extending partially through the substrate 102. The TSVs 110 may be formed to facilitate the transfer of heat and dissipation of heat within a package. The TSVs 110 may be formed, for example, by etching the substrate 102 to form openings and then filling the openings with thermally conductive material(s). For example, in some embodiments, the thermally conductive materials may comprise copper or the like. In some embodiments, the TSVs 110 may also include a liner layer (not illustrated). In some embodiments, the TSVs 110 are formed during formation of the thermal structure 104, described in greater detail below. In such embodiments, the TSVs 110 may protrude from a surface of the substrate 102 and into the thermal structure 104.

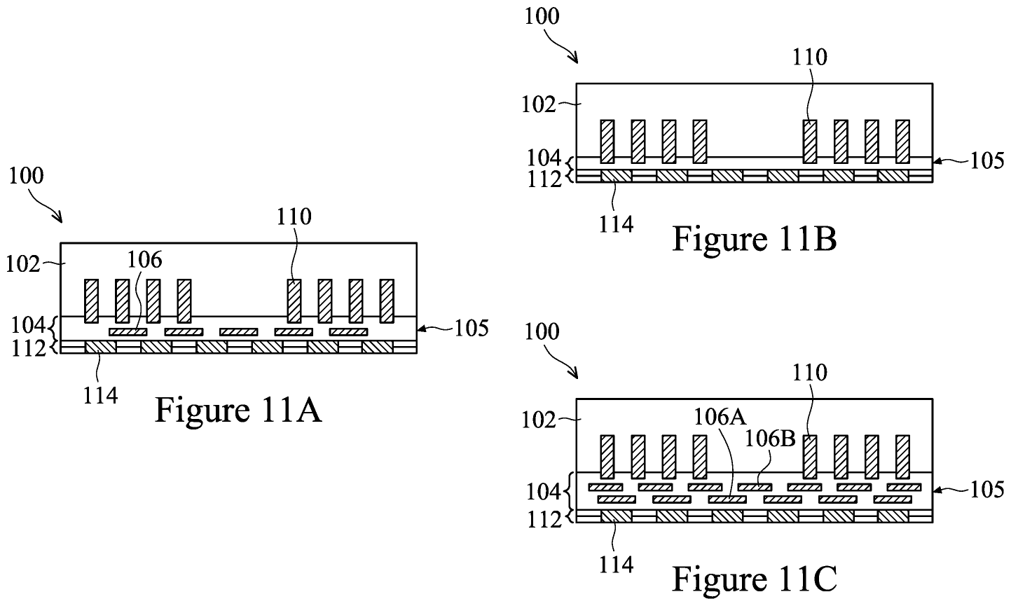

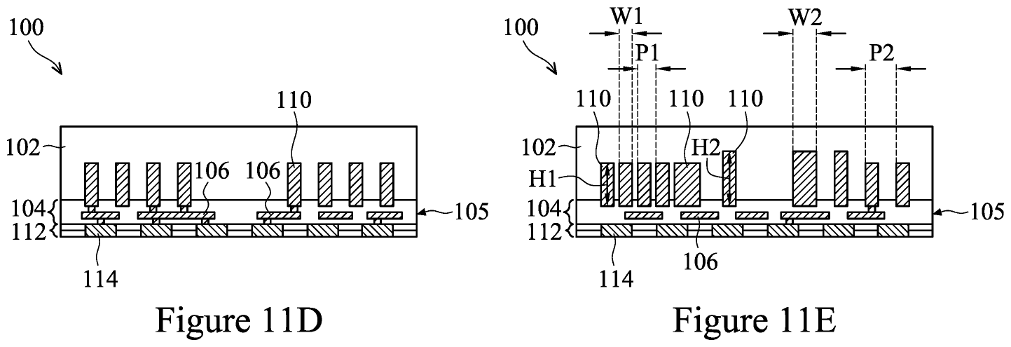

In some embodiments, a thermal structure 104 is formed over the front-side of the substrate 110. The thermal structure 104 may facilitate heat dissipation within a thermal component 100. In some embodiments, the thermal structure 104 includes one or more layers of metal features 106 (e.g., metal lines, metal vias, metal pads, etc.) formed in one or more dielectric layers 105. The metal features 106 of the thermal structure 104 may allow for more efficient transfer of heat and dissipation of heat within a package. FIG. 7 illustrates a thermal structure 104 having one layer of conductive features 106 that are separated from the TSVs 110 by one or more dielectric layers 105, but other configurations of conductive features 106 and TSVs 110 are possible. Some examples of thermal structures 104 and TSVs 110 having other configurations are described below for FIGS. 11A-11E. The conductive features 106 may be formed using a damascene process, a dual damascene process, or another suitable technique, such as those used to form the conductive features 48 of the interconnect structure 49. The metal features 106 may comprise, for example, copper, aluminum, tungsten ruthenium, cobalt, alloys thereof, combinations thereof, or the like. The dielectric layers 105 may be formed of or comprise a dielectric material such as polymer, silicon nitride, silicon oxide, silicon oxynitride, silicon oxycarbide, silicon carbonitride, the like, combinations thereof, and/or multi-layers thereof. Other materials are possible.

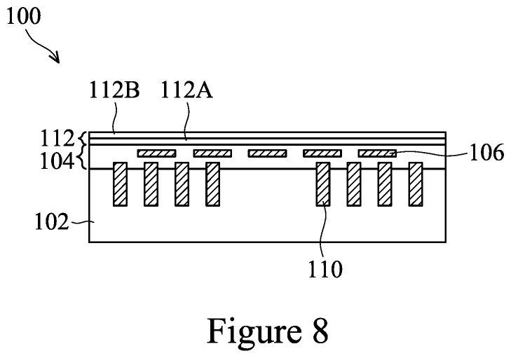

In FIG. 8, a dielectric bond layer 112 is formed on the thermal structure 104, in accordance with some embodiments. The dielectric bond layer 112 may include one layer or multiple layers. For example, the dielectric bond layer 112 is shown in FIG. 8 as being formed of a first dielectric layer 112A deposited on the thermal structure 104 and a second dielectric layer 112B deposited on the first dielectric layer 112A. In other embodiments, the dielectric bond layer 112 may be formed of a single layer or of more than two layers. The dielectric bond layer 112 may comprise material(s) similar to those described previously for the dielectric bond layer 60. For example, in some embodiments, the dielectric bond layer 112 may include a first dielectric layer 112A comprising silicon oxide and a second dielectric layer 112B comprising silicon oxynitride, though other combinations of materials are possible. In some embodiments, the dielectric bond layer 112 may have a total thickness in the range of about 100 Å to about 7000 Å, though other thicknesses are possible.

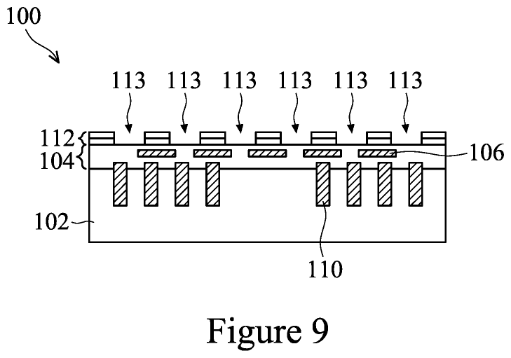

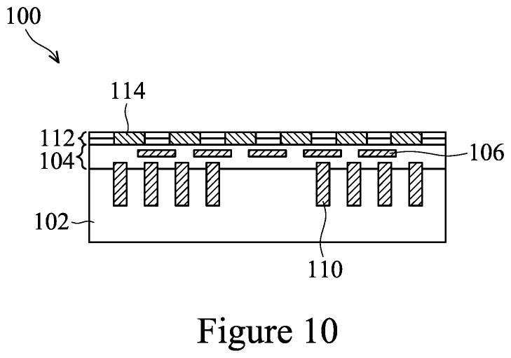

In FIG. 9, openings 113 are patterned in the dielectric bond layer 112, in accordance with some embodiments. Bond pads 114 (see FIG. 10) are subsequently formed in the openings 113. The openings 113 may expose the metal features 106 of the thermal structure 104, in some embodiments. The openings 113 may be patterned using suitable photolithography and etching techniques. For example, a patterned mask may be formed over the dielectric bond layer 112, and the dielectric bond layer 112 may be etched using the patterned mask. The etching may include one or more etching steps, each of which may include a wet etching process and/or a dry etching process.

In FIG. 10, bond pads 114 are formed in the openings 113, in accordance with some embodiments. The bond pads 114 are used to form physical, electrical, and/or thermal connections to the first package component 40. In the thermal component 100 of FIG. 10, the bond pads 114 are separated from the metal features 106 by one or more dielectric layers 105, but in other embodiments, the bond pads 114 may physically contact metal features 106. The bond pads 114 may be formed using a damascene process, a dual damascene process, or another suitable technique, such as those used to form the bond pads 62. The bond pads 114 may comprise material(s) similar to the bond pads 62 or similar to those described previously for the metal pads 50. For example, in some embodiments, a seed layer may be deposited in the openings 113 and then a conductive material may be deposited on the seed layer using a plating process. A planarization process (e.g., CMP or grinding) may be performed, in some embodiments. The planarization process may remove excess conductive material, and after performing the planarization process, surfaces of the bond pads 114 and the dielectric bond layer 112 may be approximately level or coplanar.

FIGS. 11A through 11E illustrate various example configurations of thermal components 100, in accordance with some embodiments. The thermal components 100 described for FIGS. 11A-11E are intended as a non-limiting set of examples, and other configurations are possible. Further, the various features of the thermal components 100 described for FIGS. 11A-11E may have other arrangements, dimensions, or configurations, and/or may be combined in any suitable manner. The thermal components 100 described for FIGS. 11A-11E may be similar to the thermal component 100 described previously for FIG. 10, and may be formed using similar techniques. FIGS. 11A-11E illustrate thermal components 100 in an orientation that is upside-down with respect to the thermal component 100 shown in FIG. 10.

FIG. 11A illustrates a thermal component 100 that is similar to the thermal component 100 shown in FIG. 100. For example, the thermal component 100 of FIG. 11A comprises a thermal structure 104 having one layer of metal features 106. Further, the metal features 106 are isolated from each other, from the bond pads 114, and from the TSVs 110. In the embodiment of FIG. 11A, the metal features 106 comprise metal lines or the like.

A thermal component 100 may have a thermal structure 104 with a different number of layers than shown in FIG. 11A. For example, FIG. 11B illustrates a thermal component 100 similar to that of FIG. 11A, except that the thermal structure 104 does not contain any metal features 106. In other words, the thermal structure 104 of FIG. 11B contains one or more dielectric layers 105 but no metal features 106. FIG. 11B shows TSVs 110 that are isolated from the bond pads 114 by one or more dielectric layers 105, but in other embodiments, the TSVs 110 may physically contact the bond pads 114. As another example, FIG. 11C illustrates a thermal component 100 similar to that of FIG. 11A, except that the thermal structure 104 contains two layers of metal features 106 separated by one or more dielectric layers 105. In particular, the thermal structure 104 of FIG. 11C comprises a first layer of metal features 106A (e.g., metal lines) and a second layer of metal features 106B (e.g., metal lines). In other embodiments, a thermal structure 104 may have more than two layers of metal features 106.

FIG. 11D illustrates a thermal component 100 similar to that of FIG. 11A, except that the metal features 106 of the thermal structure 104 includes metal vias in addition to metal lines. The metal vias may physically connect metal lines of the metal features 106, TSVs 110, and/or bond pads 114. The metal vias may provide thermal pathways that can improve heat dissipation within the thermal component 100. In some cases, the locations, dimensions, or arrangement of the metal vias may be chosen to provide suitably efficient heat dissipation, which may depend on the particular application or particular structure of the package. As shown in FIG. 11D, metal vias may extend between a TSV 110 and a metal line or may extend between a metal line and a bond pad 114. In other embodiments, metal vias may extend between metal lines formed in different layers.

The shapes, sizes, configurations, locations, or arrangements of the TSVs 110 or of the metal features 106 may be chosen to provide efficient heat dissipation in a package. For example, the dimensions of some TSVs 110 in a region may be larger (e.g., have greater heights and/or widths) in order to provide more efficient heat dissipation in that region. As another example, the density of TSVs 110 in a region may be larger (e.g., have a smaller pitch) in order to provide more efficient heat dissipation in that region. In this manner, the metal features 106 and/or the TSVs 110 of a thermal component 100 may be configured for a specific application or package.

As an example, FIG. 11E illustrates a thermal component 100 having TSVs 110 with different characteristics. This is an example, and TSVs 110 or metal features 106 may have different characteristics or different combinations of characteristics in other embodiments. The thermal component 100 of FIG. 11E comprises TSVs 110 of height H1 and TSVs 110 of height H2, in which height H1 and height H2 are different. For example, in FIG. 11E, the height H2 is greater than the height H1. In some embodiments, the height H1 may be between about 70% and about 90% of the height H2. In some embodiments, the heights H1 and/or H2 may be in the range of about 5 μm to about 150 μm, though other heights are possible. The thermal component 100 of FIG. 11E comprises TSVs 110 of width W1 and TSVs 110 of width W2, in which width W1 and width W2 are different. For example, in FIG. 11E, the width W2 is greater than the width W1. In some embodiments, the width W1 may be between about 5% and about 90% of the width W2. In some embodiments, the widths W1 and/or W2 may be in the range of about 1 μm to about 50 μm, though other widths are possible. The thermal component 100 of FIG. 11E comprises TSVs 110 of pitch P1 and TSVs 110 of pitch P2, in which pitch P1 and pitch P2 are different. For example, in FIG. 11E, the pitch P2 is greater than the pitch P1. In some embodiments, the pitch P1 may be between about 20% and about 90% of the pitch P2. In some embodiments, the pitches P1 and/or P2 may be in the range of about 4 μm to about 30 μm, though other pitches are possible. In other embodiments, TSVs 110 of more than two different heights, more than two different widths, and/or more than two different pitches are possible.

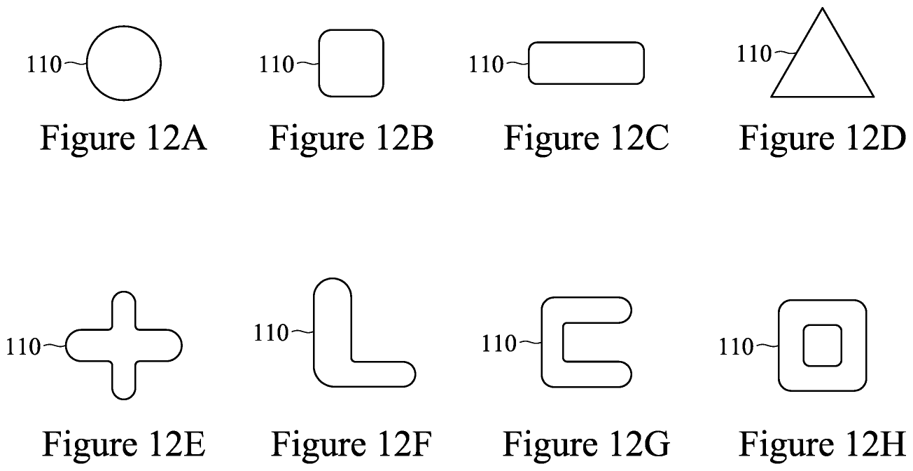

The TSVs 110 of a thermal component 100 may be formed having various shapes or configurations. The shape of a TSV 110 may be chosen to provide efficient heat dissipation according to a particular application or package. FIGS. 12A through 12H illustrate example cross-sections of a TSV 110, in accordance with some embodiments. The TSVs 110 shown in FIGS. 12A-12H are intended as non-limiting examples, and TSVs 110 having other shapes, cross-sections, or dimensions are possible.

FIGS. 12A, 12B, 12C, and 12D illustrate plan views of TSVs 110 having cross-sections of various shapes, in accordance with some embodiments. A cross-section may have a length and width that are approximately equal or may have a length that is a different distance than its width. FIG. 12A illustrates a TSV 110 having an approximately circular shape, in accordance with some embodiments. In other cases, a TSV 110 may have a round shape, an oval shape, an elliptical shape, or the like. FIG. 12B illustrates a TSV 110 having an approximately square shape, in accordance with some embodiments. In other embodiments, a TSV 110 may have an approximately rectangular shape, as shown in FIG. 12C. FIG. 12D illustrates a TSV 110 having an approximately triangular shape, in accordance with some embodiments. Other shapes are possible, such as other rectangles, other quadrilaterals, other triangles, other polygons, or the like.

FIGS. 12E, 12F, 12G, and 12H illustrate TSVs 110 having cross-sections formed of shape combinations, in accordance with some embodiments. A cross-section may have a shape that is a combination of other shapes, such as a combination of approximately rectangular segments. In some cases, shapes with larger surface area (e.g., cross-sectional perimeter) may provide improved heat dissipation. FIG. 12E illustrates a cross-section formed of two segments in a “plus” configuration. FIG. 12F illustrates a cross-section formed of two segments in an “L” configuration. FIG. 12G illustrates a cross-section formed of multiple segments in a “C” configuration. FIG. 12H illustrates a cross-section formed of multiple segments in an “O” configuration having a “hole.” In other cases, a cross-section may have more than one “hole.” Other configurations of segments or shapes are possible.

FIGS. 13 through 18 illustrate cross-sectional views of intermediate steps in the formation a package 200 (see FIG. 18), in accordance with some embodiments. In FIG. 13, one or more thermal components 100 and one or more active components 150 are attached to the first package component 40, in accordance with some embodiments. The active package components 150 may include functional components such as integrated circuits or the like. The thermal components 100 may be similar to those described previously and may be included, for example, to provide structural integrity and/or heat dissipation.

In some embodiments, the active package components 150 and/or the thermal components 100 may be attached using a direct bonding process, such as a dielectric-to-dielectric bonding process and/or a metal-to-metal bonding process (e.g., a fusion bonding process, a hybrid bonding process, or the like). Although FIG. 13 illustrates the attachment of one active package component 150 and one thermal component 100 to a first package component 40, in other embodiments any suitable number or types of active package components 150 and/or thermal components 100 may be attached to a first package component 40. For example, in other embodiments, multiple active package components 150 of various types may be attached.

In some embodiments, the active package components 150 may be individual device dies (e.g., integrated circuit dies), packages having one or more device dies packaged therein, System-on-Chip (SoC) dies including a plurality of integrated circuits (or device dies) integrated as a system, or the like. The device die(s) of the active package components 150 may comprise logic dies, memory dies, input-output (I/O) dies, Integrated Passive Devices (IPDs), the like, or combinations thereof. For example, the logic device die(s) of the active package components 150 may comprise Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) of active package components 150 may include Static Random Access Memory (SRAM) dies, Dynamic Random Access Memory (DRAM) dies, or the like. The device die(s) of the active package components 150 may include semiconductor substrates and interconnect structures. In accordance with some embodiments, first package components 40 are SoC dies, and active package components 150 comprise memory dies, such as SRAM dies.

In accordance with some embodiments (not separately illustrated), active package components 150 may include some features similar to those described above for first package components 40. For example, the active package components 150 may comprise a semiconductor substrate, integrated circuit devices, and a plurality of dielectric layers formed over the semiconductor substrate and the integrated circuit devices. The integrated circuit devices may include active devices, passive devices, or the like. The active package component 150 may comprise a dielectric bond layer 152 that is subsequently bonded to the dielectric bond layer 60. The active package components 150 may further include bond pads 154 formed within the dielectric bond layer 152.

The dielectric bond layer 152 may be similar to the dielectric bond layer 60 and/or the dielectric bond layer 112, and may be formed using similar techniques. For example, the dielectric bond layer 152 may comprise one dielectric layer or multiple dielectric layers, which may include materials such as silicon oxide, silicon nitride, silicon oxynitride, polymer, or the like. For example, in some embodiments, the dielectric bond layer 152 may include a first dielectric layer comprising silicon oxide and a second dielectric layer comprising silicon oxynitride, though other combinations of materials are possible. In some embodiments, the dielectric bond layer 152 of the active package component 150 may have a composition that is similar to that of the dielectric bond layer 112 of the thermal component 100. In other embodiments, the dielectric bond layer 152 may have different dielectric materials than the dielectric bond layer 112.

In some embodiments, the dielectric bond layer 152 and dielectric bond layer 112 may be formed of similar materials but in different proportions. For example, in some embodiments, the proportion of silicon oxide, silicon nitride, silicon oxynitride, and/or polymer within the dielectric bond layer 152 may be different from the proportion of the same material within the dielectric bond layer 112. In other words, the ratio of a thickness of a layer of dielectric material of the dielectric bond layer 152 to the total thickness of the dielectric bond layer 152 may be different from the ratio of a thickness of a layer of the same dielectric material of the dielectric bond layer 112 to the total thickness of the dielectric bond layer 112. In this manner, the dielectric layers of the dielectric bond layer 152 may have different relative thicknesses or different absolute thicknesses from corresponding dielectric layers of the dielectric bond layer 112. In some cases, forming layers of the dielectric bond layer 152 to have different thicknesses than the dielectric bond layer 112 may reduce manufacturing costs, improve bonding, and improve heat dissipation. A total thickness of the dielectric bond layer 152 may be greater than, about the same as, or less than a total thickness of the dielectric bond layer 112. For example, in some embodiments, a total thickness of the dielectric bond layer 112 may be about 70% or less than a total thickness of the dielectric bond layer 152, though other relative thicknesses are possible. In some cases, forming the dielectric bond layer 112 to be thinner than the dielectric bond layer 152 may reduce manufacturing costs, improve bonding, and improve heat dissipation. In this manner, the composition and/or thickness of bond layers of a package may be controlled to provide better thermal performance.

In some embodiments, bond pads 154 are formed in the dielectric bond layer 152 of the active package component 150. The bond pads 154 may be electrically connected to other features of the active package component 150, such as interconnect structures, circuitry, TSVs, or the like (not individually illustrated). The bond pads 154 may be similar to the bond pads 62 or bond pads 114 described previously, and may be formed using similar techniques.

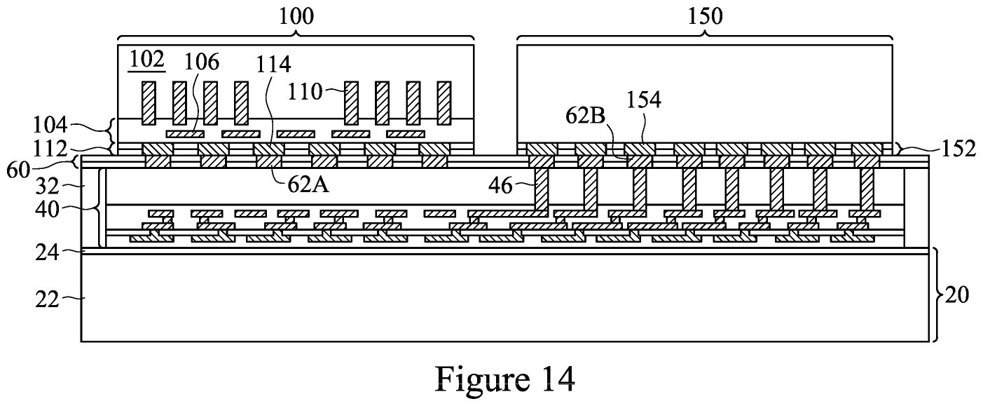

In FIG. 14, the thermal component 100 and the active package component 150 are bonded to the dielectric layer 60 formed over the first package component 40, in accordance with some embodiments. The dielectric bond layer 112 of the thermal component 100 and the dielectric bond layer 152 of the active package component 150 are directly bonded to the dielectric bond layer 60 using dielectric-to-dielectric bonding. Additionally, the bond pads 114 of the thermal component 100 are directly bonded to bond pads 62A using metal-to-metal bonding, and the bond pads 154 of the active package component 150 are directly bonded to bond pads 62B using metal-to-metal bonding. The bonding may include a pre-bonding process and an annealing process, in some embodiments. During the pre-bonding process, a small pressing force may be applied to press the thermal component 100 and the active package component 150 against the dielectric bond layer 60. The pre-bonding process may be performed at a low temperature, such as room temperature (e.g., a temperature in the range of about 20° C. to about 25° C.). After the pre-bonding process, the dielectric bond layer 112 and the dielectric bond layer 152 are bonded to the dielectric bond layer 60. The bonding strength may then be improved in a subsequent annealing step, in which the dielectric bond layers 60, 112, and 152 are annealed at a high temperature, such as a temperature in the range of about 200° C. to about 350° C. In this manner, the dielectric bond layer 112 and the dielectric bond layer 152 are bonded to the dielectric bond layer 60 by dielectric-to-dielectric bonding. Additionally, the annealing step also bonds the bond pads 114 and the bond pads 152 to the bond pads 62 by metal-to-metal bonding.

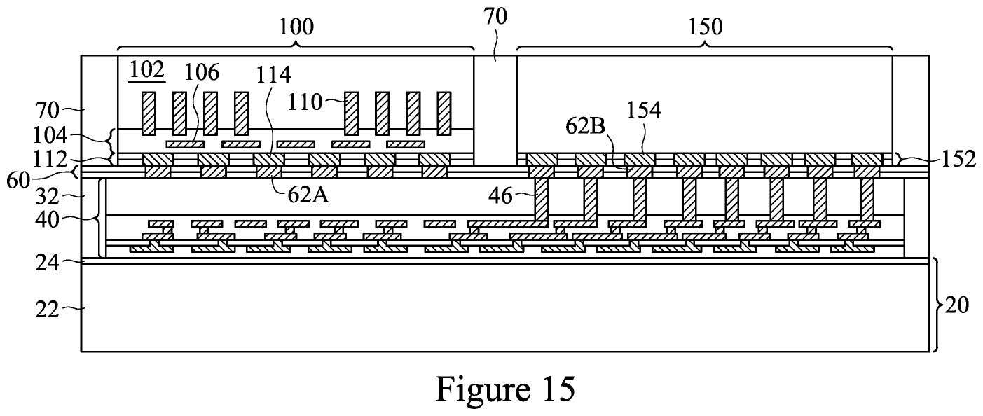

In FIG. 15, a gap-filling material 70 is deposited over the thermal component 100, the active package component 150, and the dielectric bond layer 60, in accordance with some embodiments. The gap-filling material 70 may encapsulate the over the thermal component 100 and the active package component 150. The gap-filling material 70 may be similar to the gap-filling material 32 described previously for FIG. 3, and may be formed using similar techniques. For example, the gap-filling material 70 may include an optional liner layer and a bulk layer (not separately illustrated). In some cases, the gap-filling material 70 comprises different materials than the gap-filling material 32. In some embodiments, a planarization process (e.g., CMP, grinding, or the like) is performed to remove portions of the gap-filling material 70. The planarization process may remove gap-filling material 70 such that the thermal component 100 and the active package component 150 are exposed, as shown in FIG. 15. After performing the planarization process, surfaces of the gap-filling material 70, the thermal component 100, and the active package component 150 may be level or coplanar (within process variations).

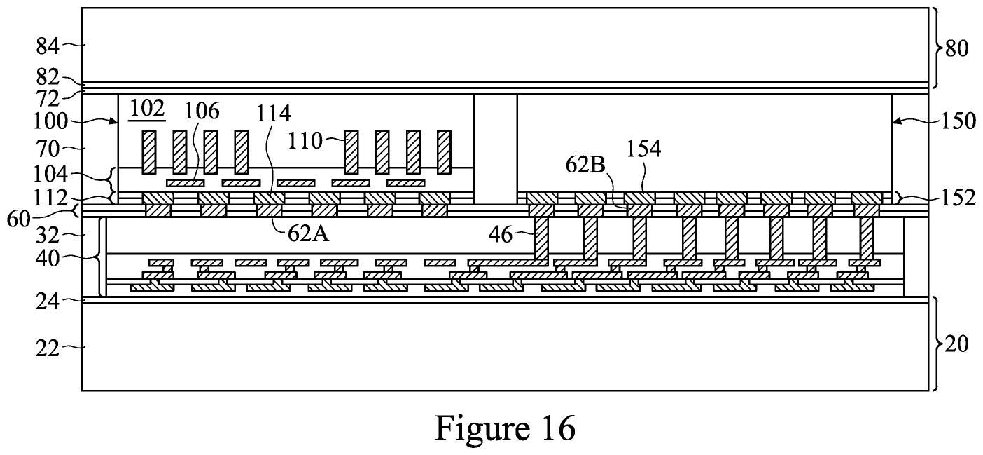

In FIG. 16, a second carrier 80 is attached, in accordance with some embodiments. The second carrier 80 may include a base carrier 84 and one or more dielectric bond layers 82. In some embodiments, the base carrier 84 and the dielectric bond layers 82 may be similar to the base carrier 22 and the dielectric bond layers 24 of the first carrier 20 described previously. For example, the base carrier 84 may be a similar material as the base carrier 22 to reduce warpage caused by CTE mismatch. Before attaching the second carrier 80, one or more dielectric bond layers 82 are deposited on the base carrier 84 and one or more dielectric bond layers 72 are deposited over the gap-filling material 70, the thermal component 100, and the active package component 150. The second carrier 80 may be attached using dielectric-to-dielectric bonding. For example, in accordance with some embodiments, the bonding of second carrier 80 includes pre-treating dielectric bond layers 72 and 82 in a process gas, performing a pre-bonding process to bond dielectric bond layers 72 and 82 together, and performing an annealing process following the pre-bonding process to strengthen the bond.

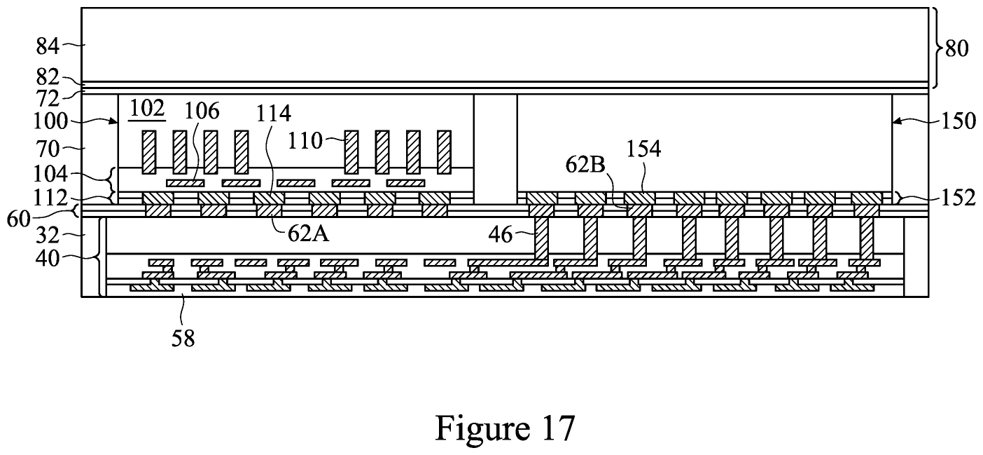

In FIG. 17, the first carrier 20 is removed, in accordance with some embodiments. The first carrier 20 may be removed using any suitable method, such as using a planarization process and/or an etching process. The planarization process may include a CMP process, a grinding process, the like, or a combination thereof. The etching process may include a wet etching process, a dry etching process, or a combination thereof. As shown in FIG. 17, removing the first carrier 20 exposes the dielectric layer 58 and the gap-filling material 32. In some embodiments, after removing the first carrier 20, surfaces of the dielectric layer 58 and the gap-filling material 32 are level or coplanar (within process variations).

In FIG. 18, under-bump metallizations (UBMs) 92 and conductive connectors 94 are formed, in accordance with some embodiments. In some embodiments, a passivation layer 90 is deposited over the first package component 40 and the gap-filling material 32. The passivation layer 90 may comprise one or more layers of dielectric materials such as silicon oxide, PSG, BSG, BPSG, FSG, USG, silicon oxynitride, silicon oxycarbide, silicon nitride, silicon carbonitride, polymer, or the like. The passivation layer 90 may be deposited using suitable techniques such as spin coating, FCVD, CVD, PECVD, or the like. In some embodiments, an optional planarization process (e.g., CMP, grinding, or the like) is performed on the passivation layer 90 such that the top surface of the passivation layer 90 is planar (within process variations).

Openings (not separately illustrated) are then formed in the passivation layer 90, in accordance with some embodiments. The openings may be formed using suitable photolithography and etching techniques. For example, a photoresist may be applied over a top surface of the passivation layer 90 and patterned. The patterned photoresist is then used as an etching mask to etch portions of the passivation layer 90, forming the openings. The etching may include one or more dry etching processes and/or wet etching processes. The openings may also extend through the dielectric layer 58 to expose metal pads 50.

Under-bump metallizations (UBMs) 92 may then be formed in the openings, in accordance with some embodiments. The UBMs 92 may extend through the passivation layer 90 and/or the dielectric layer 58 to electrically connect to the metal pads 50. As an example of forming the UBMs 92, a seed layer (not separately illustrated) is formed over the exposed surfaces of the metal pads 50 and the passivation layer 90. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 92. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 92. In other embodiments, the UBMs 66 may include a liner layer, such as an adhesion layer. In other embodiments, the UBMs 92 may have top surfaces that are level with top surfaces of the passivation layer 90.

Conductive connectors 94 may then be formed on the UBMs 92, in accordance with some embodiments. The conductive connectors 94 may comprise ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 94 may include a conductive material such as solder, copper, aluminum, gold, nickel, silver, palladium, tin, the like, or a combination thereof. In some embodiments, conductive connectors 94 are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, conductive connectors 94 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, some or all of the UBMs 92 are formed as part of the conductive connectors 94.

After forming the conductive connectors 94, a singulation process may be performed to separate the structure into individual packages 200, in accordance with some embodiments. FIG. 18 illustrates a singulated package 200, in accordance with some embodiments. The singulation process may include a sawing process, a dicing process, an etching process, or the like. In this manner, packages 200 are formed that include thermal components 100 with improved heat dissipation. This can improve the thermal performance, efficiency, and reliability of semiconductor packages such as package 200.

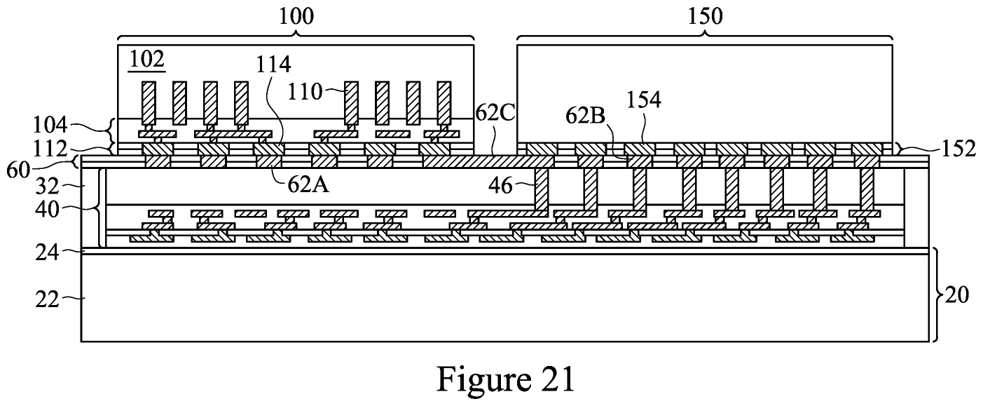

FIGS. 19 through 22 illustrate cross-sectional views of intermediate steps in the formation of a package 200, in accordance with some embodiments. The package 200 described for FIGS. 19-22 is similar to the package 200 described previously for FIG. 21, except that thermal routing 62C is formed in addition to bond pads 62A and 62B. As described below, the thermal routing 62C comprises dummy routing that may extend between bond pads 114 and bond pads 154 to provide improved heat dissipation for the package 200. The thermal routing 62C is formed using similar materials or techniques as described previously, and thus some materials, steps, and/or techniques may not be repeated below.

FIG. 19 illustrates a structure similar to that shown in FIG. 5 in which openings 61 are formed in the dielectric bond layer 60, except the openings 61 of FIG. 19 include one or more openings 61C within which thermal routing 62C is subsequently formed. The openings 61C may be formed using techniques similar to those used for forming the openings 61A-B, described previously for FIG. 5. As shown in FIG. 19, the openings 61C have a larger lateral extent than the openings 61A-B. In some cases, an opening 61C may expose one or more TSVs 46, as shown in FIG. 19. In other cases, an opening 61C may not expose a TSV 46. FIG. 19 shows a single opening 62C, but in other embodiments multiple openings 62C may be formed.

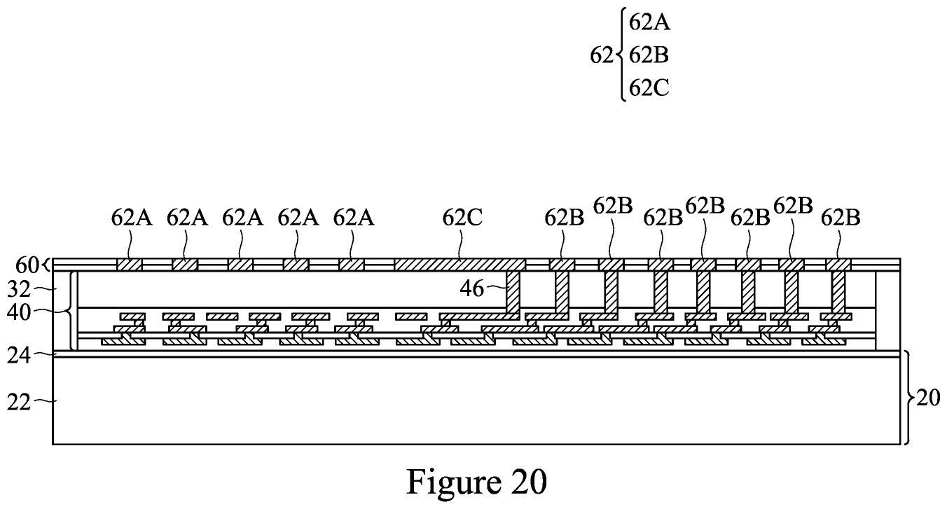

In FIG. 20, bond pads 62A-B and thermal routing 62C are formed in the openings 61A-B and openings 61C, respectively. The thermal routing 62C may be formed along with the bond pads 62A-B using the same processing steps, in some embodiments. The thermal routing 62C may be formed using materials or techniques similar to those described for the bond pads 62 in FIG. 6. For example, a conductive material may be deposited in the openings 61A-C, and then a planarization process may be performed to remove excess conductive material. As shown in FIG. 20, a thermal routing 62C may physically contact one or more TSVs 46, in some embodiments. FIG. 20 shows a single thermal routing 62C, but in other embodiments multiple thermal routing 62C may be formed.

In FIG. 21, a thermal component 100 and an active package component 150 are bonded to the dielectric bond layer 60, in accordance with some embodiments. The thermal component 100 and the active package component 150 may be bonded using techniques similar to those described for FIG. 14. For example, the dielectric bond layer 112 may be bonded to the dielectric bond layer 60 using dielectric-to-dielectric bonding, and the dielectric bond layer 152 may be bonded to the dielectric bond layer 60 using dielectric-to-dielectric bonding. Further, bond pads 114 may be bonded to bond pads 62A using metal-to-metal bonding, and bond pads 154 may be bonded to bond pads 62B using metal-to-metal bonding. As shown in FIG. 21, bond pads 114 and/or bond pads 154 may be bonded to thermal routing 62C using metal-to-metal bonding. A thermal routing 62C may be bonded to one or more bond pads 114 and/or one or more bond pads 154. Any number of thermal routing 62C may extend between two or more bond pads 62, between two or more bond pads 152, and/or between any number of bond pads 62 and any number of bond pads 152. As a non-limiting example, FIG. 21 shows a single thermal routing 62C bonded to and extending between one bond pad 114 and one bond pad 152. Forming thermal routing 62C in this manner can facilitate heat transfer and heat dissipation within the package 200. In some cases, the thermal routing 62C is dummy routing that is not electrically connected to functional circuitry. In some cases, the thermal routing 62C may electrically connect the thermal component 100 to the active package component 150 and/or to the TSVs 46.

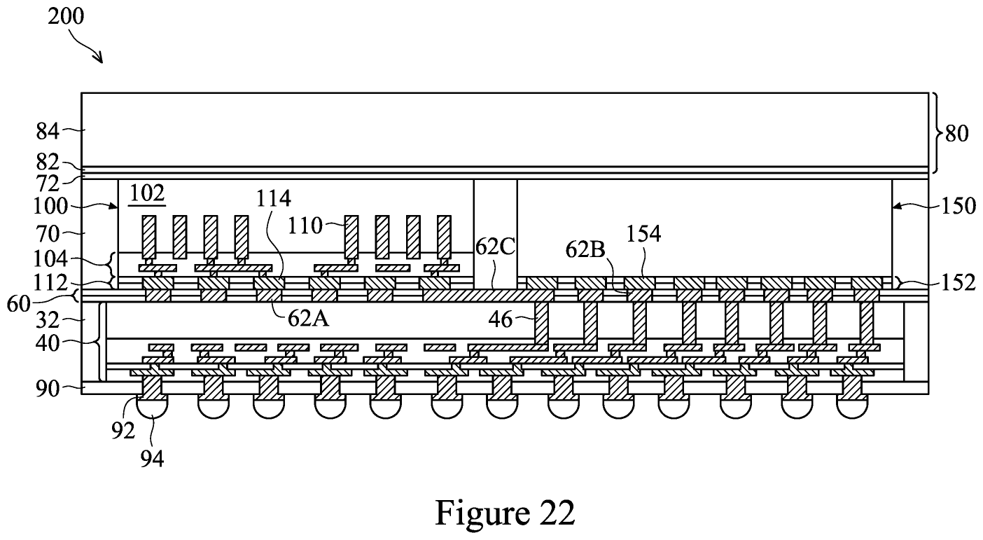

Subsequent processing steps may then be performed to form a package 200, such as that shown in FIG. 22. For example, processing steps similar to those described previously for FIGS. 15-18 may be performed. In some embodiments, the gap-filling material 70 may physically contact a top surface of a thermal routing 62C. In other cases, a thermal routing 62C may be covered by a thermal component 100 or an active package component 150. The package 200 shown in FIG. 22 is an example, and other packages or configurations of thermal routing 62C are possible.

Embodiments described herein may achieve advantages. Forming dummy structures comprising through-substrate vias (TSVs), metal lines, metal vias, and the like can provide improved heat dissipation within a package, such as a SoIC package or the like. The arrangement or characteristics of the TSVs or metal features can be controlled to provide efficient heat transfer for a specific application or package design. For example, the height, width, pitch, or shape of TSVs can be controlled for heat dissipation within a particular package design. Further, the thickness and/or composition of the bonding layer of the dummy structure can be controlled to reduce manufacturing cost, provide improved heat transfer, and/or provide improved bonding. In some embodiments, thermal routing is formed within bonding layers to further improve heat dissipation.

In accordance with some embodiments of the present disclosure, a method includes forming a dummy component, including: forming through-substrate vias (TSVs) in a substrate; forming a thermal structure over the TSVs, wherein the thermal structure includes metal lines in dielectric layers; forming a bonding layer over the thermal structure; and forming bond pads within the bonding layer; bonding the dummy component to a package component; and bonding a semiconductor die to the package component. In an embodiment, bonding the dummy component to the package component includes bonding the bonding layer to the package component using dielectric-to-dielectric bonding and bonding the bond pads to the package component using metal-to-metal bonding. In an embodiment, forming the dummy component includes forming metal vias in the dielectric layers, wherein metal vias physically contact metal lines and TSVs. In an embodiment, metal vias physically contact metal lines and bond pads. In an embodiment, the TSVs include a first set of TSVs having a first height and a second set of TSVs having a second height that is different from the first height. In an embodiment, the TSVs include a third set of TSVs having a first pitch and a fourth set of TSVs having a second pitch that is different from the first pitch. In an embodiment, the TSVs include a fifth set of TSVs having a first width and a sixth set of TSVs having a second width that is different from the first width. In an embodiment, the dummy component is electrically connected to the semiconductor die by dummy routing within the package component.

In accordance with some embodiments of the present disclosure, a method includes forming a first bonding layer on a first package component; forming first bond pads in the first bonding layer; forming second bond pads in the first bonding layer; bonding a thermal component to the first bonding layer and to the first bond pads, wherein the thermal component includes: through-substrate vias (TSVs) extending into a substrate; a second bonding layer over the substrate and the TSVs; and third bond pads in the second bonding layer; and bonding an active package component to the first bonding layer and to the second bond pads, wherein the active package component includes: active devices; a third bonding layer over the active devices; and fourth bond pads in the third bonding layer. In an embodiment, the first bond pads are electrically isolated. In an embodiment, the method includes forming thermal routing within the first bonding layer, wherein at least one third bond pad is bonded to one thermal routing. In an embodiment, at least one fourth bond pad is bonded to one thermal routing. In an embodiment, the second bonding layer is thinner than the third bonding layer. In an embodiment, a thickness of a layer of a first dielectric material within the second bonding layer is different from a thickness of a layer of the first dielectric material within the third bonding layer. In an embodiment, the first dielectric material is silicon oxide.

In accordance with some embodiments of the present disclosure, a package includes a dummy die bonded to a package component, wherein the dummy die includes: a substrate; first metal features extending into the substrate; second metal features over the first metal features and separated from the first metal features by a first dielectric layer; a second dielectric layer over the second metal features; and bond pads within the second dielectric layer; and a semiconductor die bonded to the package component adjacent the dummy die. In an embodiment, the dummy die is electrically isolated from the semiconductor die. In an embodiment, the dummy die includes at least two layers of second metal features. In an embodiment, the package component includes bond pads, wherein the bond pads of the dummy die are directly bonded to the bond pads of the package component. In an embodiment, at least one first metal feature is electrically connected to at least one metal pad of the package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a dummy component, comprising:
forming a plurality of through-substrate vias (TSVs) in a substrate;
forming a thermal structure over the plurality of TSVs, wherein the thermal structure comprises a plurality of metal lines in a plurality of dielectric layers;
forming a bonding layer over the thermal structure; and
forming a plurality of bond pads within the bonding layer;
bonding the dummy component to a package component; and
bonding a semiconductor die to the package component.

2. The method of claim 1, wherein bonding the dummy component to the package component comprises bonding the bonding layer to the package component using dielectric-to-dielectric bonding and bonding the plurality of bond pads to the package component using metal-to-metal bonding.

3. The method of claim 1, wherein forming the dummy component further comprises forming a plurality of metal vias in the plurality of dielectric layers, wherein metal vias of the plurality of metal vias physically contact metal lines of the plurality of metal lines and TSVs of the plurality of TSVs.

4. The method of claim 3, wherein metal vias of the plurality of metal vias physically contact metal lines of the plurality of metal lines and bond pads of the plurality of bond pads.

5. The method of claim 1, wherein the plurality of TSVs comprise a first set of TSVs having a first height and a second set of TSVs having a second height that is different from the first height.

6. The method of claim 1, wherein the plurality of TSVs comprise a third set of TSVs having a first pitch and a fourth set of TSVs having a second pitch that is different from the first pitch.

7. The method of claim 1, wherein the plurality of TSVs comprise a fifth set of TSVs having a first width and a sixth set of TSVs having a second width that is different from the first width.

8. The method of claim 1, wherein the dummy component is electrically connected to the semiconductor die by dummy routing within the package component.

9. A method comprising:
forming a first bonding layer on a first package component;
forming a plurality of first bond pads in the first bonding layer;
forming a plurality of second bond pads in the first bonding layer;
bonding a thermal component to the first bonding layer and to the plurality of first bond pads, wherein the thermal component comprises:
through-substrate vias (TSVs) extending into a substrate;
a second bonding layer over the substrate and the TSVs; and
a plurality of third bond pads in the second bonding layer; and
bonding an active package component to the first bonding layer and to the plurality of second bond pads, wherein the active package component comprises:
active devices;
a third bonding layer over the active devices; and
a plurality of fourth bond pads in the third bonding layer.

10. The method of claim 9, wherein the first bond pads of the plurality of first bond pads are electrically isolated.

11. The method of claim 9 further comprising forming a plurality of thermal routing within the first bonding layer, wherein at least one third bond pad is bonded to one thermal routing.

12. The method of claim 11, wherein at least one fourth bond pad is bonded to one thermal routing.

13. The method of claim 11, wherein the second bonding layer is thinner than the third bonding layer.

14. The method of claim 11, wherein a thickness of a layer of a first dielectric material within the second bonding layer is different from a thickness of a layer of the first dielectric material within the third bonding layer.

15. The method of claim 14, wherein the first dielectric material is silicon oxide.

16. A package comprising:
a dummy die bonded to a package component, wherein the dummy die comprises:
a substrate;
first metal features extending into the substrate;
second metal features over the first metal features and separated from the first metal features by a first dielectric layer;
a second dielectric layer over the second metal features; and
bond pads within the second dielectric layer; and
a semiconductor die bonded to the package component adjacent the dummy die.

17. The package of claim 16, wherein the dummy die is electrically isolated from the semiconductor die.

18. The package of claim 16, wherein the dummy die comprises at least two layers of second metal features.

19. The package of claim 16, wherein the package component comprises bond pads, wherein the bond pads of the dummy die are directly bonded to the bond pads of the package component.

20. The package of claim 16, wherein at least one first metal feature is electrically connected to at least one metal pad of the package component.
